(19) United States
(12) Patent Application Publication
(10) Pub. No.: US 2026/0033268 A1
(43) Pub. Date: Jan. 29, 2026

(54) LOAD PORT PURGE APPARATUS HAVING FLOW SENSOR FOR LEAK DETECTION

(71) Applicant: Applied Materials, Inc., Santa Clara, CA (US)

(72) Inventors: Srinivas Poshatrahalli Gopalakrishna, Bengaluru (IN); Paul Benjamin Reuter, Austin, TX (US); Devendra Channappa Holeyannavar, Nagasandra Post Bangalore (IN); Nithiyanantham Balasubramaniam, Austin, TX (US); Amit Kumar Biswas, Bangalore (IN)

(21) Appl. No.: 18/781,358

(22) Filed: Jul. 23, 2024

(51) Int. Cl. H01L 21/67; G01M 3/26

(52) U.S. Cl. CPC H01L 21/67017; G01M 3/26

(57) ABSTRACT

A purge apparatus of a load port assembly includes a gas supply configured to supply a flow of purge gas. The purge apparatus further includes one or more ports configured to provide the flow of purge gas to a substrate enclosure. The purge apparatus further includes at least one flow sensor disposed proximate the one or more ports along a purge gas flow path between the gas supply and the one or more ports. The at least one flow sensor is configured to generate sensor data indicative of the flow of purge gas along the purge gas flow path. The purge apparatus further includes a processing device communicatively coupled with the at least one flow sensor. The processing device is configured to determine, based on the sensor data, whether a purge gas leak exists along the purge gas flow path between the gas supply and the at least one flow sensor.

### TECHNICAL FIELD

This disclosure relates to electronic device manufacturing and, more particularly, to a load port assembly of an equipment front end modules (EFEMs) having a flow sensor for leak detection.

### BACKGROUND

Processing of substrates in semiconductor electronic device manufacturing is carried out in multiple process tools, where substrates travel between process tools in substrate carriers, such as, e.g., front opening unified pods (FOUPs). A substrate carrier may be docked to a load port located at a front of an equipment front end module (EFEM), where one or more substrates may be transferred to a load lock or process chamber coupled to the EFEM. In some embodiments, substrates may be transferred to a transfer chamber of a mainframe through a load lock. The mainframe may have multiple process chambers arranged around the transfer chamber. An environmentally-controlled atmosphere may be provided within and between the substrate carrier and each of the process chambers. Poor control of various environmental factors, such as, e.g., levels of humidity, oxygen, and/or chemical contaminants/particles may adversely affect substrate processing. Thus, existing electronic device manufacturing systems may benefit from improved environmental control of a substrate carrier coupled at a load port assembly of an EFEM, such as by purging FOUPS with a purge gas. However, purge apparatuses can develop leaks.

### SUMMARY

The following is a simplified summary of the present disclosure in order to provide a basic understanding of some aspects of the present disclosure. This summary is not an extensive overview of the present disclosure. It is intended to neither identify key or critical elements of the present disclosure, nor delineate any scope of the particular embodiments of the present disclosure or any scope of the claims. Its sole purpose is to present some concepts of the present disclosure in a simplified form as a prelude to the more detailed description that is presented later.

In one aspect of the present disclosure, a purge apparatus of a load port assembly includes a gas supply configured to supply a flow of purge gas. The purge apparatus further includes one or more ports configured to provide the flow of purge gas to a substrate enclosure. The purge apparatus further includes at least one flow sensor disposed proximate the one or more ports along a purge gas flow path between the gas supply and the one or more ports. The at least one flow sensor is configured to generate sensor data indicative of the flow of purge gas along the purge gas flow path. The purge apparatus further includes a processing device communicatively coupled with the at least one flow sensor. The processing device is configured to determine, based on the sensor data, whether a purge gas leak exists along the purge gas flow path between the gas supply and the at least one flow sensor.

In another aspect of the present disclosure, a system includes one or more conduits forming a purge gas flow path and configured to fluidly couple a purge gas supply at a first end of the one or more conduits and one or more ports of a load port purge apparatus at a second end of the one or more conduits. The system further includes at least one flow sensor disposed proximate the second end of the one or more conduits. The at least one flow sensor is configured to generate sensor data indicative of a flow of purge gas through the one or more conduits. The system further includes a processing device communicatively coupled with the at least one flow sensor. The processing device is configured to determine, based on the sensor data, whether a purge gas leak exists in the one or more conduits between the at least one flow sensor and the first end.

In a further aspect of the present disclosure, a method includes receiving, from at least one flow sensor, sensor data indicative of a flow of purge gas along a purge gas flow path between a gas supply and one or more ports. The at least one flow sensor is disposed proximate the one or more ports along the purge gas flow path. The method further includes determining, based on the sensor data, whether a purge gas leak exists along the purge gas flow path between the gas supply and the at least one flow sensor. The method further includes, responsive to determining the purge gas leak exists, performing a corrective action associated with the flow of purge gas.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 illustrates a side schematic view of an substrate processing system according to one or more embodiments of the present disclosure.

FIG. 2 illustrates a front perspective view of a load port assembly according to one or more embodiments of the present disclosure.

FIGS. 3A-3B illustrate schematic views of a load port purge apparatus according to one or more embodiments of the present disclosure.

FIG. 4 illustrates a simplified schematic diagram of a load port purge apparatus according to one or more embodiments of the present disclosure.

FIG. 5 is a flow diagram for determining whether a purge gas leak exists in a load port purge apparatus according to one or more embodiments of the present disclosure.

FIG. 6 is a flow chart of a method associated with a load port purge apparatus according to one or more embodiments of the present disclosure.

FIG. 7 illustrates a block diagram of an example computer system according to one or more embodiments the present disclosure.

### DETAILED DESCRIPTION OF EMBODIMENTS

Embodiments of the present disclosure provide a load port purge apparatus having a flow sensor for leak detection.

Processing of substrates in semiconductor electronic device manufacturing is carried out in multiple process tools, where substrates travel between process tools in substrate carriers, such as, e.g., front opening unified pods (FOUPs). A substrate carrier may be docked to a load port located at a front of an equipment front end module (EFEM), where one or more substrates may be transferred to a load lock or process chamber coupled to the EFEM. In some embodiments, substrates may be transferred to a transfer chamber of a mainframe through a load lock. The mainframe may have multiple process chambers arranged around the transfer chamber. An environmentally-controlled atmosphere may be provided within and between the substrate carrier and each of the process chambers. Poor control of various environmental factors, such as, e.g., levels of humidity, oxygen, and/or chemical contaminants/particles may adversely affect substrate processing.

To more closely control environmental factors in substrate processing, in some embodiments, substrate carriers (e.g., FOUPs) are purged with a purge gas when docked at a load port. The purge gas can include an inert gas such as nitrogen, another inert gas, or clean dry air (e.g., low humidity air). When introduced into a substrate carrier, the purge gas may displace contaminating gases, moisture, and/or other contaminants or particles. In some embodiments, purging the substrate carrier with purge gas reduces the relative humidity of the environment within the substrate carrier. Such substrate carrier purging may significantly reduce or eliminate harmful levels of humidity, oxygen, and/or contaminants/particles that can adversely affect substrate processing.

A purge apparatus may develop leaks, either due to component failure (e.g., due to age, use, component interference, etc.) and/or due to human factors (e.g., mis-assembly, etc.). For example, a human operator may mis-assemble components of the purge apparatus or may fail to properly reconnect components (e.g., conduit(s), fitting(s), etc.) after performing maintenance, leading to a purge gas leak. In another example, moving components may rub and/or pinch a purge gas conduit that is to deliver the purge gas to the substrate carrier. Over time, the rubbing and/or pinching may wear a hole in the conduit, leading to a purge gas leak. Leakage of purge gas can cause multiple problems. For example, leaking purge gas can pose an asphyxiant hazard within a processing facility. In another example, leaking purge gas is wasteful. In a further example, leaking purge gas can lead to a deficiency of purge gas being provided to the substrate carrier. This deficiency of purge gas can in turn lead to contamination and/or oxidation of the substrates within the substrate carrier.

Embodiments described herein provide a load port purge apparatus having a flow sensor for leak detection. In some embodiments, the load port purge apparatus described herein has the capability to monitor for leakage and flow rate during purging in real time. In some embodiments, a flow sensor is included proximate the purge gas nozzle (e.g., port, etc.) so that it can be determined whether any leaks exist in the purge gas conduit upstream of the flow sensor. In some embodiments, the apparatus described herein can be included on a load port assembly as-built or can be retro-fit to an existing load port assembly.

As described herein, in some embodiments, a purge apparatus includes a gas supply configured to supply a flow of purge gas. The gas supply may include a gas reservoir, a regulator, one or more valves, and/or a controller, etc. to supply and/or regulate the flow of purge gas. The gas supply may be included within the structure of the load port. For example, the gas supply may be housed within a lower portion of the load port. In some embodiments, the purge apparatus further includes one or more ports. The ports may be configured to provide the flow of purge gas to a substrate enclosure when the substrate enclosure is docked on the load port. In some embodiments, the ports are configured to couple with a corresponding coupling feature in a bottom surface of the substrate enclosure. In some embodiments, separate conduits deliver the purge gas from the gas supply to each of the ports. For example, a first conduit may deliver the purge gas from the gas supply to a first port, and a second conduit may deliver the purge gas from the gas supply to a second port, etc. Each of the conduits may include one or more fittings. Over time, each of the conduits may develop a leak, such as due to wear, degradation, and/or human factors, etc.

The purge apparatus described herein includes at least one flow sensor disposed proximate the one or more ports along a purge gas flow path between the gas supply and the one or more ports, in some embodiments. For example, a flow sensor may be fluidly coupled (e.g., via a conduit) between the gas supply and a purge gas port. The flow sensor may be disposed near the port such that the conduit lacks any fittings along the gas flow path between the flow sensor and the port. In some embodiments, the at least one flow sensor is configured to generate sensor data indicative of the flow of purge gas along the purge gas flow path, e.g., between the gas supply and the purge gas port.

In some embodiments, a processing device is communicatively coupled with the at least one flow sensor. The processing device may receive sensor data (e.g., flow sensor data) from the at least one flow sensor. The processing device may perform one or more data operations to determine, based on the sensor data, whether a purge gas leak exists along the purge gas flow path between the gas supply and the at least one flow sensor. For example, and in some embodiments, the processing device may monitor the flow of purge gas (e.g., indicated by the received flow sensor data) to determine when/if the flow of purge gas reduces in rate. Reduction in the rate of purge gas flow below a threshold value may indicate a leak upstream of the flow sensor along the purge gas flow path. Responsive to determining a purge gas leak exists, the processing device may perform a corrective action associated with the flow of purge gas. For example, and in some embodiments, the processing device may output an indication (e.g., to a graphical user interface) of the leak responsive to determining the leak exists. In another example, and in some embodiments, the processing device may cause the flow of purge gas to stop. Stopping the flow of purge gas may alleviate any adverse affects, such as an asphyxiant hazard and/or waste of purge gas, should a purge gas leak exist.

Embodiments of the present disclosure provide advantages over conventional solutions and apparatuses. For example, some embodiments of the present disclosure provide capability of monitoring purge gas leaks in conduits for delivering purge gas to a substrate carrier. By determining that a purge gas leak exists, the purge gas supply can be shut off so that excess purge gas is not leaked to atmosphere. Therefore, risk of asphyxiation can be minimized. Further, leaks can be identified early and the proper repairs executed. Moreover, purge gas deficiency in a substrate carrier (e.g., due to purge gas leak(s)) can be avoided, leading to more effective purging of the substrate carrier and avoidance of unwanted contamination, etc. Therefore, according to embodiments of the present disclosure, system down time can be reduced, fewer substrates may be scrapped (e.g., due to contamination, etc.), and overall system throughput can be increased.

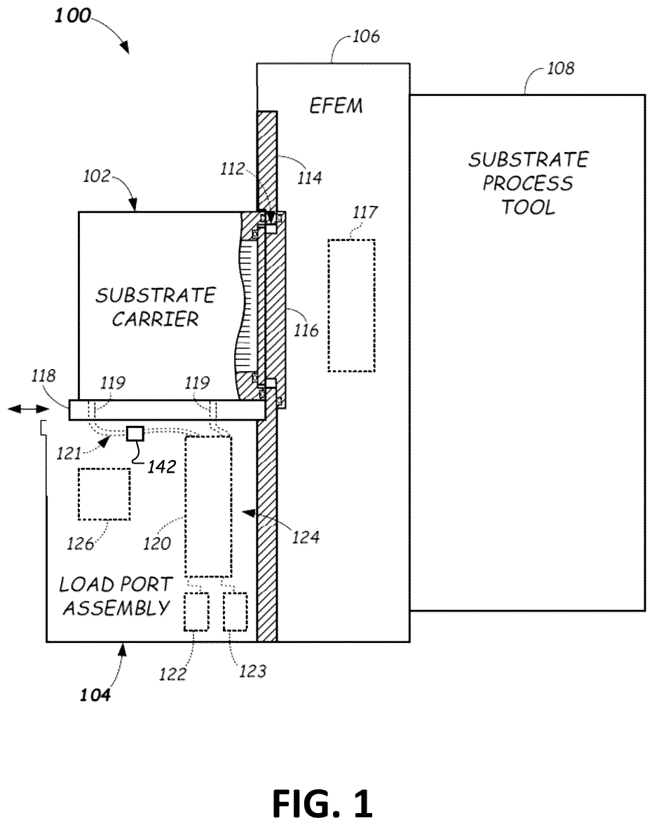

FIG. 1 illustrates a side schematic view of an substrate processing system 100 in accordance with one or more embodiments. Substrate processing system 100 may include a substrate carrier 102, a load port assembly 104, an equipment front end module (EFEM) 106, and a substrate process tool 108. Load port assembly 104 may be coupled to EFEM 106, which may be coupled to substrate process tool 108.

Substrate carrier 102 may be configured to carry one or more substrates therein. Substrates may be any suitable article used to make electronic devices or circuit components, such as silicon-containing discs or wafers, patterned wafers, unpatterned wafers, silicon-containing plates, glass plates, or the like. Substrate carrier 102 may be a bottom purge substrate carrier having two or more purge ports (not shown) located therein. In some embodiments, substrate carrier 102 may be, e.g., a front opening unified pod (FOUP). As shown in FIG. 1, substrate carrier 102 may include a carrier door 110 received within a panel opening 112 (a load port) of a panel 114 of load port assembly 104.

Load port assembly 104 may be configured to receive substrate carrier 102 thereon and may include a carrier door opener 116 configured to contact (that is, e.g., latch onto or otherwise attach to) carrier door 110, open carrier door 110, and move the carrier door 110 out of the way to allow the transfer of substrates into and out of substrate carrier 102 through the opening (load port) 112 by a load/unload robot 117 (shown as a dotted box) in the EFEM 106. In some embodiments, carrier door opener 116 may contact carrier door 110, move carrier door 110 inward sufficiently to clear panel 114 (i.e., to right as shown in FIG. 1), and then move carrier door 110 away (e.g., downward) to provide access into substrate carrier 102.

Load port assembly 104 may include a receiving plate 118 configured to receive and clamp a substrate carrier 102 thereon. Receiving plate 118 may have two or more gas nozzles 119 formed on or extending through receiving plate 118 for connection to purge connections or ports (not shown) in the bottom of substrate carrier 102 wherein the two or more gas nozzles 119 are connected to exhaust and delivery gas lines 121 in the load port assembly 104. The term “gas nozzle” as used herein means any structure capable of a detachable connection with the purge ports of the substrate carrier 102 enabling gas flow between exhaust and delivery gas lines 121 and an internal chamber of the substrate carrier 102. Several examples of a “gas nozzle” include a tube or hollow protuberance, a port, a hole, and the like. The gas nozzle engages with a mating purge port formed on the substrate carrier 102, such as a purge connection or port to form a sealed flow connection there between thus producing a sealed gas flow passageway. Any suitable configuration of nozzle and purge port enabling a rapidly coupled and decoupled configuration may be used.

Load port assembly 104 may also include purge apparatus 120 having exhaust and delivery gas lines 121 each connected to a respective gas nozzle 119 for purging a substrate carrier coupled to the Receiving plate 118 of load port assembly 104. Purge apparatus 120 may also have a delivery inlet connected to a gas source 122 (or to a connection to a gas source if the gas source is located outside of load port assembly 104). Purge apparatus 120 may further have an exhaust outlet connected to an exhaust system 123 (or to a connection to an exhaust system if the exhaust system is located outside of load port assembly 104). Purge apparatus 120 may be located in a lower portion 124 of load port assembly 104.

One or more flow sensors 142 may be coupled to a gas line 121 between the purge apparatus 120 and a gas nozzle 119. The flow sensor 142 may measure the flow of purge gas through the gas line 121. A processing device may receive sensor data from the flow sensor 142. The processing device may determine that a purge gas leak exists in the gas line 121 between the flow sensor 142 and the purge apparatus 120 when the sensor data indicates less than a threshold amount of purge gas is flowing through the gas line 121. Similarly, the processing device may determine that a purge gas leak exists in the gas line 121 between the flow sensor 142 and the purge apparatus 120 when the sensor data indicates less than a target amount of purge gas is flowing through the gas line 121. In some embodiments, a flow sensor 142 is included on each of the gas lines 121. More details regarding the flow sensor 142 and/or determination of a purge gas leak are described herein below.

Along with purge apparatus 120, other apparatus (not shown), such as, e.g., vacuum pumps, actuators, sensors, gauges, valves, elevator for the door opener 116, other gas supply lines and sources, and/or the like, may be disposed within and/or coupled to substrate processing system 100 to provide one or more of substrate carrier 102, load port assembly 104, EFEM 106, and substrate process tool 108 with an environmentally-controlled atmosphere (e.g., in a non-reactive and/or inert gas environment, under vacuum, and the like).

Load port assembly 104 may further include a controller 126 that may control the operation of load port assembly 104 including, e.g., clamping and release of substrate carrier 102 to and from receiving plate 118, motion (e.g., docking and undocking motion) of the receiving plate 118, operation of carrier door opener 116, and operation of purge apparatus 120. Controller 126 may include, e.g., a general purpose computer, a programmable processor, and/or other suitable CPU (central processing unit); a memory for storing processor executable instructions/software programs/firmware; various support circuits (such as, e.g., power supplies, clock circuits, circuits for driving receiving plate 118 and carrier door opener 116, circuits for opening and closing flow control meters and/or other valves in purge apparatus 120, and/or the like); and input/output circuits for communicating through a GUI to permit entry and display of data, operating commands, and the like by a human operator. Controller 126 may operate in conjunction with a system controller (not shown) of substrate processing system 100. Controller 126 may receive commands from and exchange information with such a system controller. Alternatively, in some embodiments, control of load port assembly 104 (including purge apparatus 120) may be shared by controller 126 and a system controller or, in other embodiments, load port assembly 104 (including purge apparatus 120) may be completely controlled by a system controller of substrate processing system 100, wherein controller 126 may be omitted from load port assembly 104.

EFEM 106 may be any suitable enclosure having one or more panel openings 112 (load ports) each configured as part of a respective load port assembly 104. EFEM 106 may include a load/unload robot (not shown) configured to transfer substrates from substrate carrier 102 through EFEM 106 to substrate process tool 108.

Substrate process tool 108 may perform one or more processes, such as deposition (e.g., physical vapor deposition (PVD) or chemical vapor deposition (CVD) and the like), etching, annealing, pre-cleaning, heating, degassing, metal or metal oxide removal, and the like, on one or more substrates. Other processes may be carried out on substrates therein. Substrate process tool 108 may include one or more load lock chambers, a transfer chamber, and one or more process chambers (none shown). The one or more load lock chambers may be coupled to EFEM 106, while the transfer chamber may be coupled to the one or more load lock chambers and to the one or more process chambers. The load/unload robot of EFEM 106 may transfer substrates into and out of the one or more load lock chambers, or directly to a process chamber in some embodiments. Substrate process tool 108 may, in some embodiments, include a transfer robot (not shown) at least partially housed within the transfer chamber. The transfer robot may be configured to transfer substrates to and from the one or more load lock chambers and the one or more process chambers.

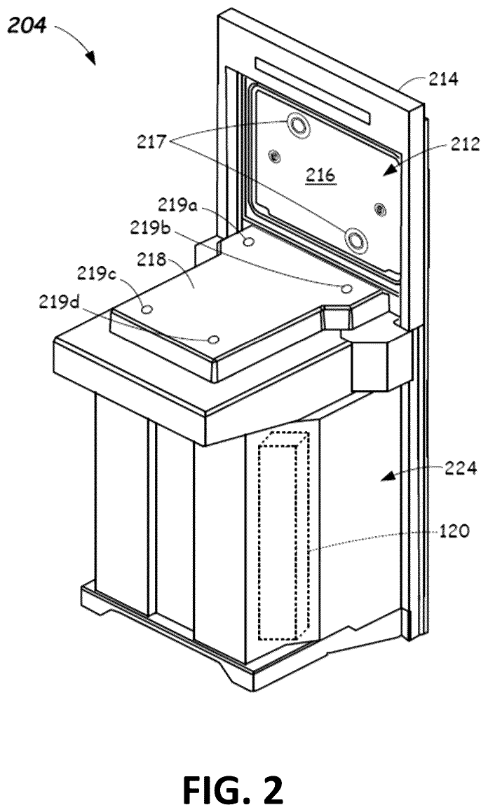

FIG. 2 illustrates a front perspective view of a load port assembly 204 in accordance with one or more embodiments. Load port assembly 204 may be identical or similar to load port assembly 104. Load port assembly 204 may include a panel 214 having a panel opening 212 comprising a load port. Load port assembly 204 may also include a carrier door opener 216 that functions to seal panel opening 212 when carrier door opener 216 is closed against panel 214. Carrier door opener 216 may have one or more connectors 217 configured to contact and attach to carrier door 110 (FIG. 1) of substrate carrier 102. Connectors 217 may be, e.g., suction type devices, vacuum devices, mechanical connectors, and the like. Other suitable types of connector devices capable of attaching to carrier door 110 may be used.

Load port assembly 204 may further include a receiving plate 218 that extends horizontally outward from panel 214. Receiving plate 218 may be configured to receive substrate carrier 102 thereon. Various mechanisms (not shown) may be included on, coupled to, and/or around receiving plate 218 to lock or clamp substrate carrier 102 into a docking position on receiving plate 218 and/or to move the receiving plate 218 into sealing engagement with the load port. Receiving plate 218 may include a plurality of gas nozzles 219a-219d. One or more of gas nozzles 219a-219d may be used to supply a gas to substrate carrier 102, and one or more of gas nozzles 219a-219d may be used to exhaust a gas from substrate carrier 102. For example, in some embodiments, gas nozzle 219a may be used to exhaust a gas from substrate carrier 102, while gas nozzles 219b-219d may be used to supply a gas to substrate carrier 102. Other combinations are possible. In some embodiments, only gas nozzles 219a and 219b may be present, wherein gas nozzle 219a may be used to exhaust a gas from substrate carrier 102, and gas nozzle 219b may be used to supply a gas to substrate carrier 102, or vice-versa.

Load port assembly 204 includes a lower portion 224 that may house purge apparatus 120 therein. Purge apparatus 120 may be easily installed in lower portion 224 by, e.g., mounting to a vertical frame member in lower portion 224. Lower portion 224 may also house one or more of the following (none shown): an opening/closing and elevator mechanism coupled to carrier door opener 216, a controller (e.g., controller 126), a gas source (e.g., gas source 122) or a connection thereto, and/or a gas exhaust system (e.g., exhaust system 123) or a connection thereto. In some embodiments, one or more flow sensors are coupled between the gas source and one or more of the gas nozzles 219a-219d. Sensor data from the one or more flow sensors can be used to identify purge gas leak(s).

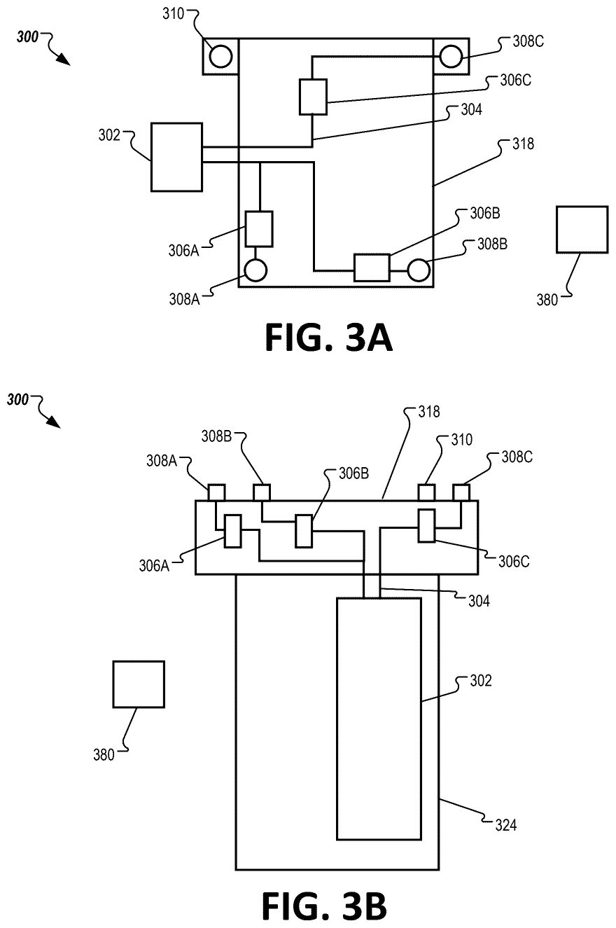

FIGS. 3A-3B illustrate schematic views of a load port purge apparatus 300 according to one or more embodiments of the present disclosure. Referring to FIG. 3A, a top-down view of apparatus 300 is shown. Referring to FIG. 3B, a sideview of apparatus 300 is shown.

A lower portion 324 of a load port houses a purge gas unit 302. In some embodiments, the purge gas unit 302 includes a purge gas supply. The purge gas supply may be a reservoir (e.g., a tank, etc.) containing purge gas. The purge gas can be nitrogen, another inert gas, or clean dry air. In some embodiments, a flow of purge gas is supplied from the purge gas unit 302 to purge gas ports 308A-308C via purge gas lines 304. In some embodiments, the purge gas unit 302 includes one or more valves to control the flow and/or flow rate of purge gas supplied to the ports 308A-308C. Each of the ports 308A-308C may be used to supply purge gas to a substrate carrier docked on the receiving plate 318. For example, and in some embodiments, each of the ports 308A-308C are configured to couple with a corresponding coupling feature formed in a bottom surface of a substrate carrier, such as a grommet, etc. Purge gas may flow from each of the ports 308A-308C into the substrate carrier. When purge gas is supplied into a substrate carrier, exhausted gas may be provided from the substrate carrier into an exhaust port 310. Contaminants such as particles, moisture, other gases, etc. within the substrate carrier may be displaced by the purge gas and exhausted out of the substrate carrier via the exhaust port 310.

The apparatus 300 may include flow sensors 306A-306C on each of the flow lines 304. In some embodiments, the flow sensors 306A-306C each are an in-line flow sensor and/or a non-contact flow sensor. The flow sensors 306A-306C may include a corresponding flow sensor for each of the ports 308A-308C. In some embodiments, each of the flow sensors 306A-306C measure the flow rate of purge gas flowing to the corresponding nozzles 308A-308C along the purge gas flow path(s) formed by the flow lines 304. For example, flow sensor 306A measures the flow rate of purge gas flowing along a flow path from the purge gas unit 302 to the nozzle 308A, flow sensor 306B measures the flow rate of purge gas flowing along a flow path from the purge gas unit 302 to the nozzle 308B, and flow sensor 306C measures the flow rate of purge gas flowing along a flow path from the purge gas unit 302 to the nozzle 308C.

Flow rate sensor data may be provided from the flow rate sensors 306A-306C to a controller 380. A processing device of the controller 380 may analyze the sensor data to determine whether a purge gas leak exists in any of the flow lines 304. In some embodiments, during a purge operation, the processing device monitors the flow rate sensor data. To conserve computing power, the flow rate sensor data may not be monitored by the processing device except during a purge operation. For example, the processing device may monitor the sensor data responsive to initiation of a purge operation. Initiation of a purge operation may include the opening of a purge gas valve, etc. to supply purge gas to a substrate carrier. In some embodiments, the processing device determines the flow rate of purge gas based on the sensor data. Responsive to determining that less than a threshold amount of purge gas (e.g., a threshold flow rate) is flowing through the corresponding flow line 304, the processing device may determine a purge gas leak exists. For example, upon determining that sensor data from flow rate sensor 306B indicates less than a threshold flow rate, the processing device may determine a leak exists in the corresponding flow line 304. In some embodiments, the threshold flow rate is between approximately 5 SLM (standard liters per minute) and approximately 60 SLM. In some embodiments, the threshold flow rate is between approximately 10 SLM and approximately 40 SLM. In some embodiments, the threshold flow rate is between approximately 15 SLM and approximately 30 SLM. The threshold flow rate may be determined based on the interior size of the substrate carrier docked at the receiving plate 318.

The processing device of the controller 380 may compare the measured purge gas flow rate indicated by the flow rate sensor data (e.g., from one or more of the flow rate sensors 306A-306C) to a target purge gas flow rate. For example, during a purge operation, a target flow rate of purge gas may be provided to a substrate carrier via one or more of ports 308A-308C. One or more of the flow rate sensors 306A-306C may measure the flow rate of purge gas provided. The processing device may compare the measured purge gas flow rate value to the target purge gas flow rate value. Upon determining the measured purge gas flow rate is less than the target purge gas flow rate, the processing device may determine a purge gas leak exists in the flow line 304 coupled to the appropriate flow rate sensor.

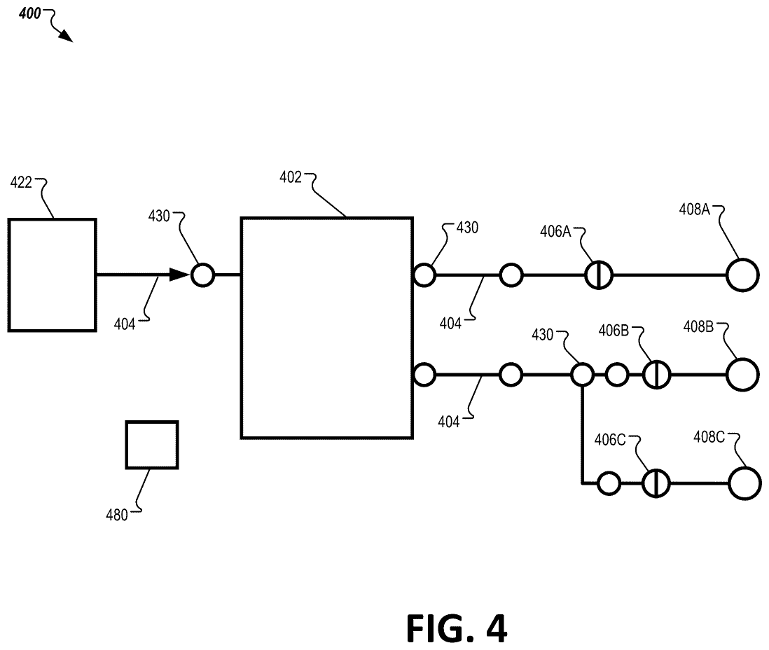

FIG. 4 illustrates a simplified schematic diagram of a load port purge apparatus 400 according to one or more embodiments of the present disclosure. In some embodiments, a gas source 422 provides a purge gas (e.g., nitrogen, another inert gas, clean dry air, etc.) to a gas unit 402. The purge gas may be provided via a gas flow line 404. A fitting 430 may couple the gas flow line 404. In some embodiments, a fitting 430 can be a coupling fitting, an elbow fitting, an adapter fitting, a flange fitting, a valve fitting, a T fitting, etc. The gas unit 402 may include one or more flow lines, manifolds, valves, etc. for distributing the purge gas. For example, and in some embodiments, the gas unit 402 may include a manifold that is to distribute purge gas to be supplied to ports 408A-408C. Ports 408A-408C may correspond to ports 308A-308C of FIGS. 3A-3B.

Purge gas may be supplied to each of the ports 408A-408C by flow lines 404. The flow lines 404 may each be conduits extending from the gas unit 402 to the corresponding port 408A-408C. The flow lines 404 may each form purge gas flow paths for the purge gas. A flow rate sensor 406A-406C may be coupled to the flow lines 404 to measure the flow rate of purge gas flowing in the corresponding flow line 404. Flow rate sensors 406A-406C may correspond to flow rate sensors 306A-306C of FIGS. 3A-3B. In some embodiments, the flow lines 404 include one or more fittings 430. The fittings 430 may be disposed along the purge gas flow path between the gas unit 402 and the flow sensors 406A-406C. In some embodiments, the fittings 430 are disposed along the purge gas flow path(s) (e.g., formed by the flow lines 404) upstream of the flow sensors 406A-406C. For example, and in some embodiments, the flow line 404 to supply purge gas to the port 408A lacks any fittings 430 between the flow sensor 406A and the port 408A. The fittings 430 on the flow line are disposed between the gas unit 402 and the flow sensor 406A. By excluding any fittings 430 between the flow sensors 406A-406C and the ports 408A-408C, risk of leakage between the flow sensors 406A-406C and the ports 408A-408C can be reduced and an accurate measurement of purge gas flow rate through the ports 408A-408C can be measured (e.g., by flow sensors 406A-406C).

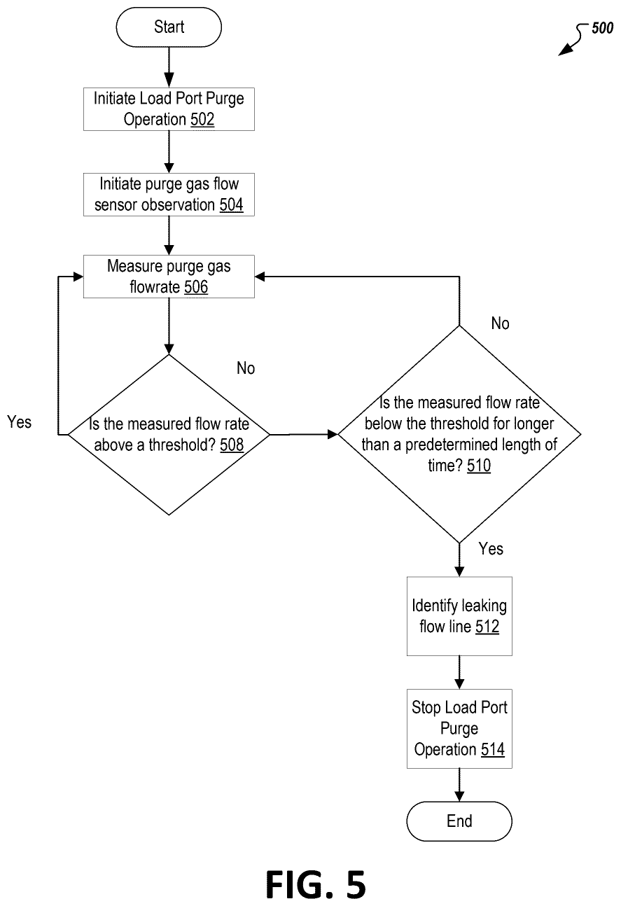

FIG. 5 is a flow diagram 500 for determining whether a purge gas leak exists in a load port purge apparatus according to one or more embodiments of the present disclosure. At operation 502, a load port purge operation is initiated. In some embodiments, a load port purge operation includes providing a purge gas to a substrate carrier docked at a load port, such as by a load port purge apparatus as described herein. Initiation of the load port purge operation may include providing a flow of purge gas to the substrate carrier by one or more conduits which form one or more purge gas flow paths. A flow sensor may be disposed along each of the one or more purge gas flow paths for monitoring the flow of purge gas along the respective purge gas flow path.

At operation 504, purge gas flow sensor observation is initiated. In some embodiments, sensor data from the one or more flow sensors is provided to a processing device. However, the processing device may only monitor the received flow sensor data responsive to initiation of the load port purge operation at 502. By monitoring the received flow sensor data only when a load port purge operation is actively taking place, computing power in the processing device can be conserved.

At operation 506, the purge gas flow rate is measured. In some embodiments, the processing device determines the purge gas flow rate from the received flow sensor data. At operation 508, the processing device determines whether the measured purge gas flow rate is above a threshold flow rate. In some embodiments, the threshold flow rate is between approximately 5 SLM (standard liters per minute) and approximately 60 SLM. In some embodiments, the threshold flow rate is between approximately 10 SLM and approximately 40 SLM. In some embodiments, the threshold flow rate is between approximately 15 SLM and approximately 30 SLM. If the measured flow rate is above the threshold, the process flow returns to operation 506 and the purge gas flow rate is continued to be measured. If the measured flow rate is below the threshold, the process flow proceeds to operation 510.

At operation 510, the processing device determines whether the measured flow rate is below the threshold for longer than a predetermined length of time. Due to variances in purge gas supply, the purge gas flow rate can fluctuate. Fluctuations in purge gas flow rate due to purge gas supply variances are often temporary and are not indicative of a leak. Fluctuations or decreases in purge gas flow rate due to leaks may be reflected in the flow rate sensor data for longer periods of time (e.g., longer than the predetermined length of time). For example, the purge gas flow rate may decrease from an initial due to a variance in the purge gas supply. However, the purge gas flow rate may quickly increase back to the initial value. This quick decrease in purge gas flow rate may not be indicative of a leak. In another example, the purge gas flow rate may decrease from an initial value due to a leak. The purge gas flow rate may be prevented from returning to the initial value because of the leak. By determining that the measured flow rate is below the threshold value for longer than the predetermined length of time, “false positives” in the flow rate sensor data may be avoided. In some embodiments, the predetermined length of time is longer than approximately 2 seconds. In some embodiments, the predetermined length of time is between 5 seconds and 15 seconds. In some embodiments, the predetermined length of time is between 8 seconds and 12 seconds. In some embodiments, the predetermined length of time is approximately 10 seconds.

If the measured flow rate is below the threshold for longer than the predetermined length of time, the process flow proceeds to operation 512. If the measured flow rate is not below the threshold for longer than the predetermined length of time, the process flow returns to operation 506.

At operation 512, the leaking flow line is identified. In some embodiments, multiple sets of sensor data from multiple flow sensors, each associated with a parallel flow line, is monitored. The leaking purge gas flow line associated with the low purge gas flow rate may be identified, such as for performing a maintenance operation, or for performing another corrective action, etc.

At operation 514, the load port purge operation is stopped. The load port purge operation may be stopped such as for performing a maintenance operation with respect to the leaking purge gas flow line and/or to mitigate leakage from the leaking purge gas flow line. In some embodiments, stopping the load port purge operation may be to limit the asphyxiant hazard posed by the leaking purge gas flow line.

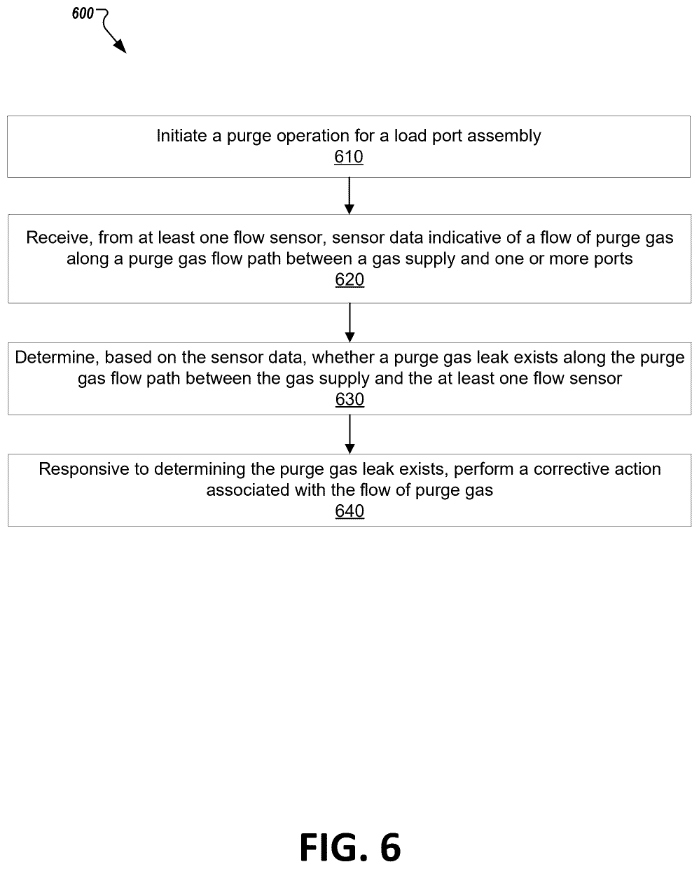

FIG. 6 is a flow chart of a method 600 associated with a load port purge apparatus according to one or more embodiments of the present disclosure. For simplicity of explanation, method 600 is depicted and described as a series of operations. However, operations in accordance with this disclosure can occur in various orders and/or concurrently and with other operations not presented and described herein. Furthermore, not all illustrated operations may be performed to implement method 600 in accordance with the disclosed subject matter.

At operation 610, processing logic (e.g., of a processing device such as controller 380 or controller 480, etc.) initiates a purge operation for a load port assembly. The purge operation may include providing purge gas to a substrate carrier docked at the load port as described herein above.

The processing logic may cause the purge gas to be provided such as by causing one or more flow valves and/or control valves to open to provide a flow of purge gas.

At operation 620, processing logic receives, from at least one flow sensor, sensor data indicative of a flow of purge gas along a purge gas flow path between a gas supply and one or more ports. In some embodiments, the at least one flow sensor includes an in-line flow sensor and/or a non-contact flow sensor coupled along a conduit that forms the purge gas flow path. In some embodiments, the at least one flow sensor includes multiple flow sensors, each flow sensor associated with a respective purge gas flow path. In some embodiments, the sensor data is indicative of a flow rate of the purge gas along the purge gas flow path. In some embodiments, processing logic monitors the received sensor data responsive to initiation of the purge operation at 610.

At operation 630, processing logic determines, based on the sensor data, whether a purge gas leak exists along the purge gas flow path between the gas supply and the at least one flow sensor. A decrease in purge gas flow rate below a threshold flow rate value may indicate such a purge gas leak. For example, if the sensor data received at operation 620 indicates the purge gas flow rate falls below a threshold flow rate, a purge gas leak may exist.

At operation 640, responsive to determining the purge gas leak exists, processing logic may perform a corrective action associated with the flow of purge gas. In some embodiments, the corrective action includes outputting an indication (e.g., such as to a GUI) of the purge gas, and/or causing the flow of purge gas to stop. Other corrective actions are possible.

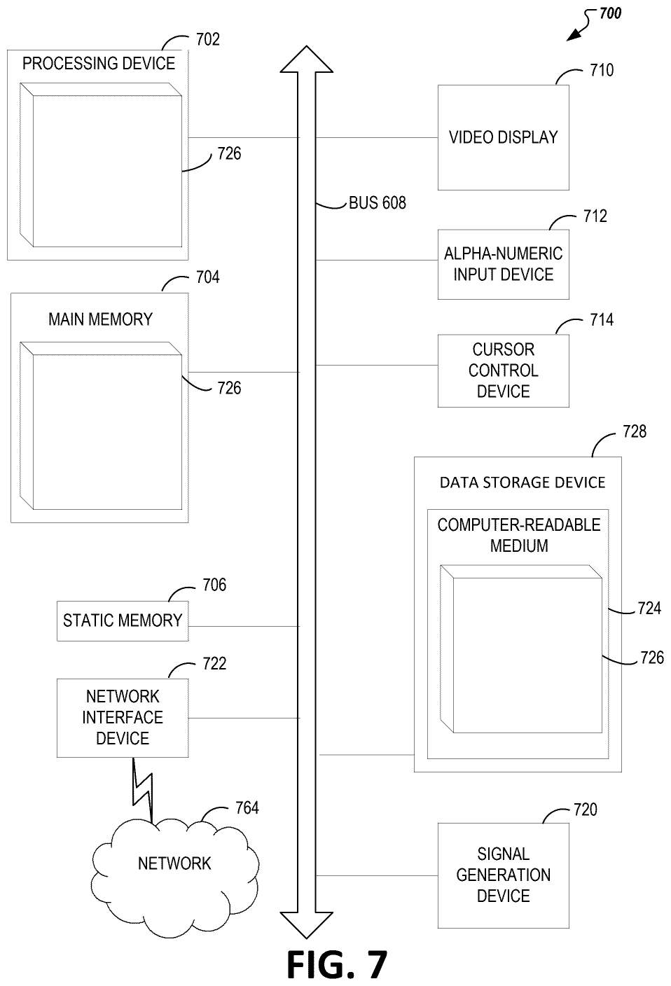

FIG. 7 illustrates a block diagram of an example computer system 700 according to one or more embodiments the present disclosure. In alternative embodiments, the computer system 700 can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing system 700 can correspond to one or more of controllers 380, 480 as described herein.

The example computing system 700 includes a processing device 702, a main memory 704 (e.g., read-only memory (ROM), flash memory, dynamic random access memory (DRAM) such as synchronous DRAM (SDRAM), etc.), a static memory 706 (e.g., flash memory, static random access memory (SRAM), etc.), and a secondary memory (e.g., a data storage device 728), which communicate with each other via a bus 708.

Processing device 702 can represent one or more general-purpose processors such as a microprocessor, central processing unit, or the like. More particularly, the processing device 702 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. Processing device 702 can also be or include a system on a chip (SoC), programmable logic controller (PLC), or other type of processing device. Processing device 702 is configured to execute the processing logic for performing operations discussed herein.

The computing system 700 can further include a network interface device 722 for communicating with a network 764. The computing system 700 also can include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 720 (e.g., a speaker).

The data storage device 728 can include a machine-readable storage medium (or more specifically a non-transitory machine-readable storage medium) 724 on which is stored one or more sets of instructions 726 embodying any one or more of the methodologies or functions described herein. A non-transitory storage medium refers to a storage medium other than a carrier wave. The instructions 726 can also reside, completely or at least partially, within the main memory 704 and/or within the processing device 702 during execution thereof by the computer system 700, the main memory 704 and the processing device 702 also constituting computer-readable storage media.

While the computer-readable storage medium 724 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the present disclosure should, therefore, be determined with reference to the appended claims, along with the full scope of equivalents to which such claims are entitled.

What is claimed is:

1. A purge apparatus of a load port assembly, comprising:
a gas supply configured to supply a flow of purge gas;
one or more ports configured to provide the flow of purge gas to a substrate enclosure;
at least one flow sensor disposed proximate the one or more ports along a purge gas flow path between the gas supply and the one or more ports, wherein the at least one flow sensor is configured to generate sensor data indicative of the flow of purge gas along the purge gas flow path; and
a processing device communicatively coupled with the at least one flow sensor, wherein the processing device is configured to determine, based on the sensor data, whether a purge gas leak exists along the purge gas flow path between the gas supply and the at least one flow sensor.

2. The purge apparatus of claim 1, wherein the purge gas flow path is formed by a purge gas conduit extending from the gas supply to the one or more ports, wherein the purge gas conduit comprises one or more fittings, and wherein the one or more fittings are disposed along the purge gas flow path between the gas supply and the at least one flow sensor.

3. The purge apparatus of claim 2, wherein the purge gas conduit lacks the one or more fittings along the purge gas flow path between the at least one flow sensor and the one or more ports.

4. The purge apparatus of claim 1, wherein the processing device is configured to determine the purge gas leak exists responsive to determining, based on the sensor data, less than a threshold amount of purge gas is flowing along the purge gas flow path.

5. The purge apparatus of claim 4, wherein the processing device is configured to determine the purge gas leak exists further responsive to determining, based on the sensor data, less than the threshold amount of purge gas is flowing along the purge gas flow path for a predetermined length of time.

6. The purge apparatus of claim 1, wherein the processing device is configured to:
compare a measured purge gas flow rate indicated by the sensor data to a target purge gas flow rate; and
determine the purge gas leak exists responsive to determining the measured purge gas flow rate is less than the target purge gas flow rate.

7. The purge apparatus of claim 1, wherein the processing device is configured to monitor the sensor data responsive to initiation of a purge operation.

8. The purge apparatus of claim 1, wherein the at least one flow sensor comprises an in-line flow sensor or a non-contact flow sensor.

9. The purge apparatus of claim 1, wherein the at least one flow sensor comprises a corresponding flow sensor for each of the one or more ports.

10. The purge apparatus of claim 1, wherein each of the one or more ports are configured to couple with a corresponding coupling feature formed in a bottom surface of the substrate enclosure.

11. A system, comprising:
one or more conduits forming a purge gas flow path and configured to fluidly couple a purge gas supply at a first end of the one or more conduits and one or more ports of a load port purge apparatus at a second end of the one or more conduits;
at least one flow sensor disposed proximate the second end of the one or more conduits, wherein the at least one flow sensor is configured to generate sensor data indicative of a flow of purge gas through the one or more conduits; and
a processing device communicatively coupled with the at least one flow sensor, wherein the processing device is configured to determine, based on the sensor data, whether a purge gas leak exists in the one or more conduits between the at least one flow sensor and the first end.

12. The system of claim 11, wherein the one or more conduits comprise one or more fittings, and wherein the one or more fittings are disposed along the purge gas flow path between the first end and the at least one flow sensor.

13. The system of claim 11, wherein the processing device is configured to determine the purge gas leak exists responsive to determining, based on the sensor data, less than a threshold amount of purge gas is flowing through the one or more conduits.

14. The system of claim 13, wherein the processing device is configured to determine the purge gas leak exists further responsive to determining, based on the sensor data, less than the threshold amount of purge gas is flowing through the one or more conduits for longer than a predetermined length of time.

15. The system of claim 11, wherein the processing device is configured to monitor the sensor data responsive to initiation of a purge operation.

16. A method, comprising:
receiving, from at least one flow sensor, sensor data indicative of a flow of purge gas along a purge gas flow path between a gas supply and one or more ports, wherein the at least one flow sensor is disposed proximate the one or more ports along the purge gas flow path;
determining, based on the sensor data, whether a purge gas leak exists along the purge gas flow path between gas supply and the at least one flow sensor; and
responsive to determining the purge gas leak exists, performing a corrective action associated with the flow of purge gas.

17. The method of claim 16, wherein determining the purge gas leak exists comprises determining, based on the sensor data, less than a threshold amount of purge gas is flowing along the purge gas flow path.

18. The method of claim 17, wherein determining the purge gas leak exists comprises determining, based on the sensor data, less than a threshold amount of purge gas is flowing along the purge gas flow path for longer than a predetermined length of time.

19. The method of claim 16, further comprising:
comparing a measured purge gas flow rate indicated by the sensor data to a target purge gas flow rate; and
determining the purge gas leak exists responsive to determining the measured purge gas flow rate is less than the target purge gas flow rate.

20. The method of claim 16, further comprising:
initiating a purge operation for a load port assembly; and
monitoring the received sensor data responsive to initiating the purge operation, wherein the corrective action comprises causing the flow of purge gas to stop.
